(19) United States
(12) Patent Application Publication
(10) Pub. No.: US 2004/0092056 A1
(43) Pub. Date: May 13, 2004

(54) Multilayer memory stacking method and multilayer memory made by the method

(76) Inventor: Cheng-Hsun Tsai, Hsin-Chu (TW)

Correspondence Address: LAW OFFICES OF DAVID PAI, 1001 FOURTH AVENUE, SUITE 3200, SEATTLE, WA, 98154, US

(21) Appl. No.: 10/291,907

(22) Filed: Nov. 13, 2002

(51) Int. Cl. H01L 21/44

(52) U.S. Cl. 438/109; 438/107

(57) ABSTRACT

A multilayer memory stacking method for stacking two lead frame-packed memory chips into a multilayer memory is disclosed including the steps of (a) applying a solder material to the lead wires of the upper memory chip, (b) placing solder balls on the solder material at the lead wires of the upper memory chip, (c) aligning the solder balls and the lead wires of the upper memory chip with the lead wires of the lower memory chip and keeping the solder balls in contact with the lead wires of the lower memory chip, and (d) heating the lead wires of the memory chips to melt the solder balls so as to bond the lead wires of the lower memory chip to the lead wires of the upper memory chip respectively.

### BACKGROUND OF THE INVENTION

1. Field of the Invention

The present invention relates to a multilayer memory stacking method for fabricating multilayer memory devices and more particularly to such a multilayer memory stacking method which uses solder balls to connect memory chips in a stack.

2. Description of the Related Art

In a computer system, the CPU determines system performance, and the capacity and operating speed of the memory are important factors that affect data processing efficiency. Nowadays, memory devices are designed to have a high storage capacity with a reduced size. The most cost effective method is to stack multiple memory chips into a multilayer memory.

FIG. 1 shows a multilayer memory according to the prior art. According to this design, the first memory chip 6 is provided at the bottom side, the second memory chip 7 is provided at the top side, and the lead wires 71 of the second memory chip 7 are respectively bonded to the lead wires 61 of the first memory chip 6 manually by soldering paste. This design of multilayer memory is widely accepted for the advantage of low manufacturing cost. However, because this multilayer memory fabricating method consumes much labor, it is not suitable for mass production.

FIG. 2 shows another design of multilayer memory according to the prior art. According to this design, an interface material (for example, a hard or flex circuit board) 8 is provided in between the bottom first memory chip 6 and the top second memory chip 7. The second memory chip 7 has its lead wires 71 respectively bonded to the interface material 8 with soldering paste. The interface material 8 has lead wires 9 extended out of the two opposite sides thereof and respectively connected to the lead wires 61 of the first memory chip 6. The manufacturing cost of this design is much higher than the design shown in FIG. 1.

FIG. 3 shows still another design of multilayer memory according to the prior art. According to this design, the interface material 8 has a lead frame 81, the lead wires 61 of the first memory chip 6 are respectively electrically connected to the lead frame 81 at the bottom side, and the lead wires 71 of the second memory chip 7 are respectively bonded to the surface of the interface material 8. Through the electric loop of the interface material 8, the first memory chip 6 and the second memory chip 7 are electrically connected. The manufacturing cost of this design is also high.

FIG. 4 shows still another design of multilayer memory according to the prior art. According to this design, the first memory chip 6 has conductor blocks 62 respectively upwardly protruded from the lead wires 61 of the first memory chip 6 and respectively bonded to the bottom side of the interface material 8, and the lead wires 71 of the second memory chip 7 are respectively bonded to the top surface of the interface material 8. This design has drawbacks. It is difficult to process the conductor blocks 62. Because the conductor blocks 62 must have a thickness not less than 0.25 mm, there is a limitation to the miniaturization of multilayer memory. Further, the manufacturing cost of this design is very high.

### BRIEF SUMMARY OF THE INVENTION

The present invention has been accomplished under the circumstances in view. The main object of the present invention is to provide a multilayer memory stacking method, which is suitable for mass production of high performance memory devices. Another object of the present invention is to provide a multilayer memory which is inexpensive to manufacture. The multilayer memory stacking method is adapted to stack a lead frame-packed first memory chip having a plurality of lead wires and a lead frame-packed second memory chip having a plurality of lead wires into a multilayer memory having the second memory chip located on the top side of the first memory chip, the memory chip stacking method comprising the steps of (a) applying a solder material to the lead wires of the second memory chip; (b) placing grain-like conductor elements on the solder material at the lead wires of the second memory chip; (c) aligning the grain-like conductor elements and the lead wires of the second memory chip with the lead wires of the first memory chip, and keeping the grain-like conductor elements in contact with the lead wires of the first memory chip; and (d) heating the lead wires of the first memory chip and the second memory chip to melt the grain-like conductor elements so as to bond the lead wires of the first memory chip to the lead wires of the second memory chip respectively. The grain-like conductor elements can be solder balls. Further, an interface material, for example, a circuit board may be provided between the lead wires of the first memory chip and the solder balls at the lead wires of the second memory chip.

### BRIEF DESCRIPTION OF THE DRAWINGS

FIG. 1 is a schematic side view of a multilayer memory according to the prior art.

FIG. 2 is a schematic side view of another structure of multilayer memory according to the prior art.

FIG. 3 is a schematic side view of still another structure of multilayer memory according to the prior art.

FIG. 4 is a schematic side view of still another structure of multilayer memory according to the prior art.

FIG. 5 is a side view of a multilayer memory according to first embodiment of the present invention.

FIG. 6 is another side view of the multilayer memory shown in FIG. 5 when viewed from another angle.

FIG. 7 is a side view of a multilayer memory according to the second embodiment of the present invention.

FIG. 8 is another side view of the multilayer memory shown in. FIG. 7 when viewed from another angle.

FIG. 9 is a side view of a multilayer memory according to the third embodiment of the present invention.

FIG. 10 is a side view of a multilayer memory according to the fourth embodiment of the present invention.

FIG. 11 is a side view of a multilayer memory according to the fifth embodiment of the present invention.

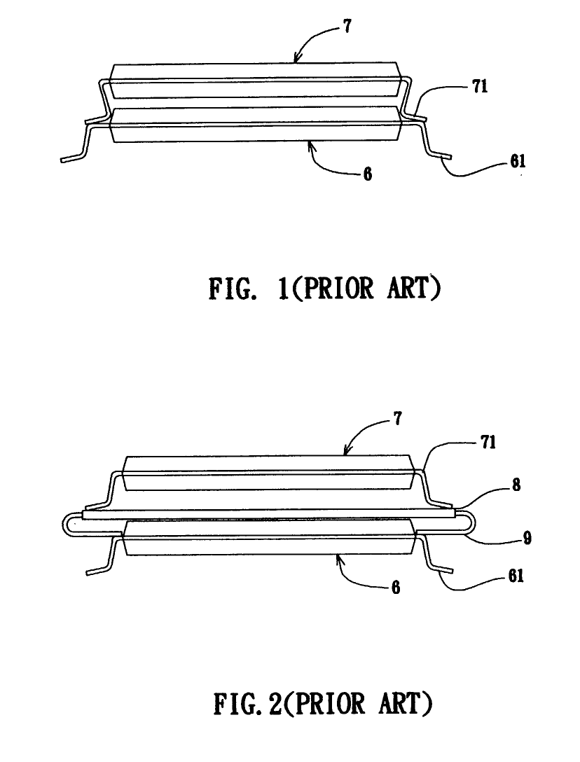

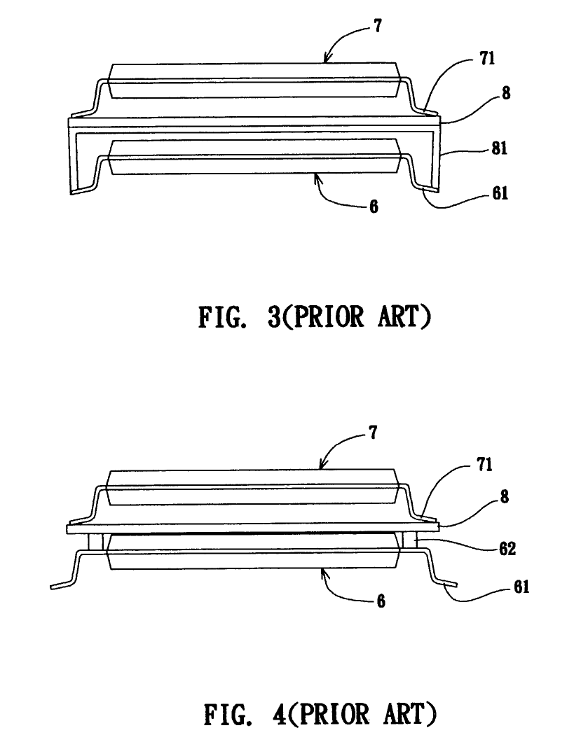

### DETAILED DESCRIPTION OF THE PREFERRED EMBODIMENT

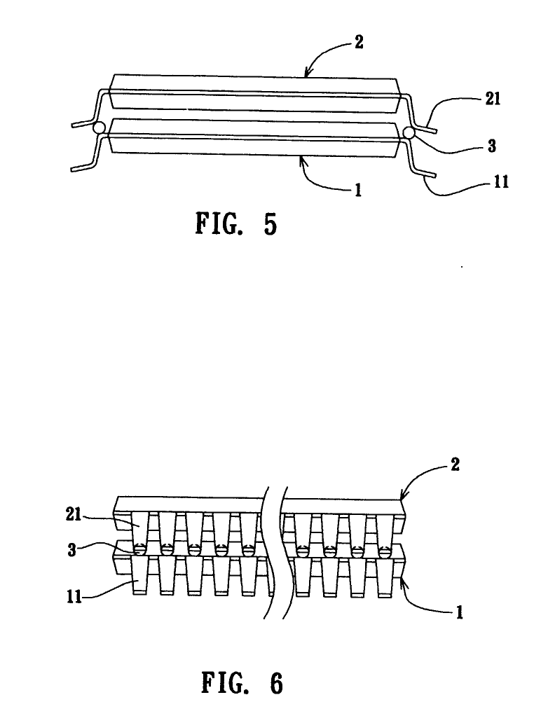

FIGS. 5 and 6 show a multilayer memory, which comprises a first memory chip 1 and a second memory chip 2 arranged in a stack. The second memory chip 2 is provided at the top side of the first memory chip 1. The first memory chip 1 and the second memory chip 2 each have lead wires 11 or 21 symmetrically arranged at two sides. Further, grain-like conductor elements 3 are respectively connected between the lead wires 11 of the first memory chip 1 and the lead wires 21 of the second memory chip 2 to achieve electric connection between the first memory chip 1 and the second memory chip 2. The grain-like conductor elements 3 can be solder balls. Other suitable electrically conducting materials may be used to make the grain-like conductor elements 3 in any of a variety of shapes.

The fabricating method of the aforesaid multilayer memory comprises the steps of:

1. Soldering flux application, wherein a brush is used to apply soldering flux to the lead wires 21 of the second memory chip 2;

2. Solder ball placing, wherein a mold having holes corresponding to the lead wires 21 of the second memory chip 2 is prepared and attached to the lead wires 21 of the second memory chip 2, and then solder balls 3 are respectively placed in the holes of the mold for enabling solder balls 3 to be respectively positioned on the lead wires 21 at the bottom side;

3. Solder ball aligning, wherein the lead wires 21 of the second memory chip 2 and the attached solder balls 3 are set into alignment with the lead wires 11 of the first memory chip 1, keeping the solder balls 3 in contact with the lead wires 11 of the first memory chip 1;

4. Binding, wherein the lead wires 11 of the first memory chip 1 and the lead wires 21 of the second memory chip 2 are heated to melt the solder balls 3, thereby causing the lead wires 11 of the first memory chip 1 and the lead wires 21 of the second memory chip 2 to be bonded together.

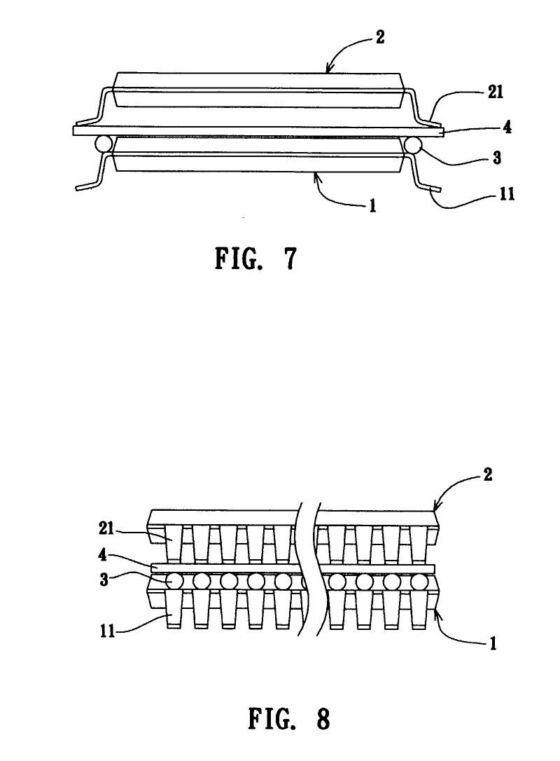

FIGS. 7 and 8 show a multilayer memory constructed according to the second embodiment of the present invention. According to this embodiment, an interface material 4 is provided in between the first memory chip 1 and the second memory chip 2, the solder balls 3 are connected between the lead wires 11 of the first memory chip 1 and the bottom side of the interface material 4, and the lead wires 21 of the second memory chip 2 are respectively bonded to the top side of the interface material 4. Through the interface material 4, the first memory chip 1 and the second memory chip 2 are electrically connected.

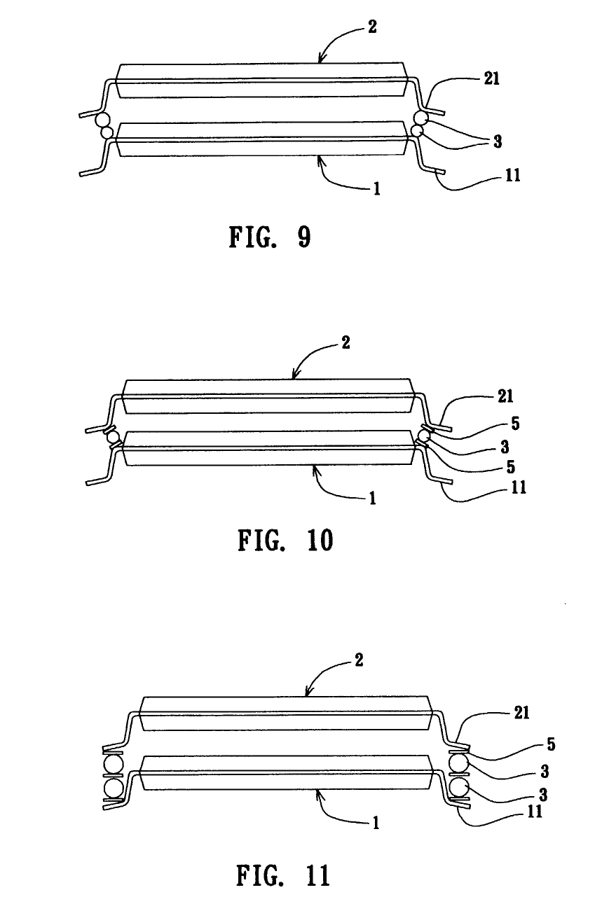

FIG. 9 shows a multilayer memory constructed according to the third embodiment of the present invention. According to this embodiment, a plurality of solder balls 3 are connected in a line between each lead wire 11 of the first memory chip 1 and the corresponding lead wire 21 of the second memory chip 2.

FIG. 10 shows a multilayer memory constructed according to the fourth embodiment of the present invention. According to this embodiment, solder pads 5 are respectively provided between the solder balls 3 and the lead wires 11 and 21 of the memory chips 1 and 2.

FIG. 11 shows a multilayer memory constructed according to the fifth embodiment of the present invention. According to this embodiment, solder pads 5 are respectively provided between the solder balls 3 and the lead wires 11 and 21 of the memory chips 1 and 2, and between every two vertically spaced adjacent solder balls 3.

The multilayer memory stacking method of the present invention is suitable for mass production to reduce the manufacturing cost of the desired multilayer memory. Because solder balls can quickly and accurately be placed and aligned, a multilayer memory made according to the present invention achieves a high performance.

Although particular embodiments of the invention have been described in detail for purposes of illustration, various modifications and enhancements may be made without departing from the spirit and scope of the invention. Accordingly, the invention is not to be limited except as by the appended claims.

What is claimed is:

1. A multilayer memory stacking method for stacking a lead frame-packed first memory chip having a plurality of lead wires and a lead frame-packed second memory chip having a plurality of lead wires into a multilayer memory having said second memory chip located on a top side of said first memory chip, the memory chip stacking method comprising the steps of:
i) applying a solder material to the lead wires of said second memory chip;
ii) placing grain-like conductor elements on said solder material at the lead wires of said second memory chip;
iii) aligning said grain-like conductor elements and the lead wires of said second memory chip with the lead wires of said first memory chip, and keeping said grain-like conductor elements in contact with the lead wires of said first memory chip; and
iv) heating the lead wires of said first memory chip and said second memory chip to melt said grain-like conductor elements so as to bond the lead wires of said first memory chip to the lead wires of said second memory chip respectively.

2. The multilayer memory stacking method as claimed in claim 1, wherein said step ii) is achieved by attaching a mold having holes corresponding to the lead wires of said second memory chip to the lead wires of said second memory chip, and then placing said grain-like conductor elements in the holes of said mold for enabling said grain-like conductor elements to be respectively positioned on the lead wires of said second memory chip at a bottom side.

3. The multilayer memory stacking method as claimed in claim 1, wherein at least two of said grain-like conductor elements are placed on each lead wire of said second memory chip and connected in a line during said step ii).

4. The multilayer memory stacking method as claimed in claim 1, wherein said step iii) further comprises providing an interface material between said grain-like conductor elements and the lead wires of said second memory chip, for enabling said first memory chip to be electrically connected to said second memory chip through said interface material.

5. A multilayer memory made according to the multilayer stacking method of claim 1.

6. The multilayer memory as claimed in claim 5, further comprising an interface material provided between said grain-like conductor elements and the lead wires of said second memory chip, for enabling said first memory chip to be electrically connected to said second memory chip through said interface material.

7. The multilayer memory as claimed in claim 5, wherein at least two of said grain-like conductor elements are connected in a line between each lead wire of said second memory chip and the corresponding lead wire of said first memory chip.

8. The multilayer memory as claimed in claim 5, wherein said grain-like conductor elements are solder balls.
